(19) United States
(12) Patent Application Publication
(10) Pub. No.: US 2016/0049319 A1
(43) Pub. Date: Feb. 18, 2016

(54) PACKAGING INSERT

(71) Applicant: E.PAK INTERNATIONAL, INC., Austin, TX (US)

(72) Inventors: James R. THOMAS, Austin, TX (US); Clifton C. HAGGARD, Austin, TX (US)

(21) Appl. No.: 14/778,696

(22) PCT Filed: Mar. 26, 2014
(86) PCT No.: PCT/US2014/031860

§ 371 Date: Sep. 21, 2015

Related U.S. Application Data
(60) Provisional application No. 61/805,254, filed on Mar. 26, 2013.

(51) Int. Cl. H01L 21/673

(52) U.S. Cl. CPC H01L 21/67383; H01L 21/6732

(57) ABSTRACT

A packaging insert includes a frame that is configured to occupy a selected amount of space within a container at least in an area corresponding to a periphery of the container contents, such as silicon wafers. The packing insert includes a plurality of spring members projecting from the frame at an oblique angle relative to a reference surface on the frame. The spring members are configured to flex or move responsive to contact with a surface on the container as the container is closed. The resiliency of the spring members provides a secure positioning of the packaging insert within the container that facilitates maintaining the contents of the container, such as silicon wafers, in a desired condition within the container.

### BACKGROUND

When packaging delicate items, such as silicon wafers, it is necessary to ensure that those items are appropriately secured within a container. For example, silicon wafers can be damaged as a result of lateral or axial movement of the wafers within the container. Lateral movement involves wafers within a stack moving side-to-side relative to the stacked arrangement (e.g., wafers slide relative to each other). Axial movement involves wafers within a stack moving in a direction aligned with the stacked arrangement (e.g., wafers move toward or away from each other). Either type of movement may result in damage to the delicate wafers or any circuitry formed on them.

A variety of wafer container configurations have been proposed and various methods of packing wafers within containers are known. Some of those have features or components that are intended to resist undesired wafer movement.

### SUMMARY

According to an example embodiment of this invention, a packaging insert includes a frame that is configured to occupy a selected amount of space within a container at least in an area corresponding to a periphery of the container contents, such as silicon wafers. The packing insert includes a plurality of spring members projecting from the frame at an oblique angle relative to a reference surface on the frame. The spring members are configured to flex or move responsive to contact with a surface on the container as the container is closed. The resiliency of the spring members provides a secure positioning of the packaging insert within the container that facilitates maintaining the contents of the container, such as silicon wafers, in a desired condition within the container.

An example embodiment of a packaging insert comprises a frame portion that establishes an outer periphery of the insert and a plurality of spring members projecting from the frame portion at an oblique angle relative to a surface on the frame portion.

In an embodiment having one or more features of the packaging insert of the previous paragraph, the frame portion has an unchanging thickness.

In an embodiment having one or more features of the packaging insert of either of the previous paragraphs, the spring members are at least partially resilient and at least partially moveable relative to the frame portion or at least partially flexible.

In an embodiment having one or more features of the packaging insert of any of the previous paragraphs, the spring members establish a first overall thickness of the insert in a first position and a second, smaller overall thickness of the insert in a second position corresponding to the spring members being flexed or moved relative to the frame portion.

In an embodiment having one or more features of the packaging insert of any of the previous paragraphs, the frame portion comprises a ring and the spring members project inward toward a center of the ring.

In an embodiment having one or more features of the packaging insert of any of the previous paragraphs, the frame portion has a generally rectangular cross-section.

In an embodiment having one or more features of the packaging insert of any of the previous paragraphs, the spring members are generally planar.

An example embodiment of an assembly, comprises a container including a base and a lid, the container having a storage area between the base and lid, a stack of wafers situated in the storage area, the stack of wafers occupying less than an available space within the storage area, and at least one packaging insert within the storage area, the at least one packaging insert having a frame portion and a plurality of spring members projecting from the frame portion at an oblique angle relative to a surface on the frame portion.

In an embodiment having one or more features of the assembly of the previous paragraph, the at least one packaging insert is situated between the stack of wafers and an interior surface on at least one of the lid or the base, and the interior surface contacts the spring members of the at least one packaging insert in a manner that causes the spring members to flex or move relative to the frame portion such that the spring members bias the packaging insert toward the stack of wafers.

In an embodiment having one or more features of the assembly of either of the previous paragraphs, the at least one packaging insert comprises a plurality of packaging inserts, and the spring members of only one of the packaging inserts flex or move responsive to contact with the interior surface.

In an embodiment having one or more features of the assembly of any of the previous paragraphs, the frame portion and the spring members have a first overall thickness when the container is open and a second, smaller thickness when the container is closed with the lid is secured to the base.

In an embodiment having one or more features of the assembly of any of the previous paragraphs, the spring members are situated relative to the frame portion differently when the container is closed with the lid secured to the base compared to when the container is open.

In an embodiment having one or more features of the assembly of any of the previous paragraphs, the frame portion has an unchanging thickness.

In an embodiment having one or more features of the assembly of any of the previous paragraphs, the spring members are at least partially resilient and at least partially moveable relative to the frame portion or at least partially flexible.

In an embodiment having one or more features of the assembly of any of the previous paragraphs, the spring members establish a first overall thickness of the packaging insert in a first position and a second, smaller overall thickness of the packaging insert in a second position corresponding to the spring members being flexed or moved relative to the frame portion.

In an embodiment having one or more features of the assembly of any of the previous paragraphs, the frame portion comprises a ring, and the spring members project inward toward a center of the ring.

In an embodiment having one or more features of the assembly of any of the previous paragraphs, the frame portion has a generally rectangular cross-section.

In an embodiment having one or more features of the assembly of any of the previous paragraphs, the spring members are generally planar.

### BRIEF DESCRIPTION OF THE DRAWINGS

FIG. 1 is a perspective view of an example embodiment of a packaging insert designed according to an embodiment of this invention.

FIG. 2 is an elevational view of the example of FIG. 1 as seen from a top of the insert.

FIG. 3 is an elevational view of the example packaging insert as seen from a side of the insert.

FIG. 4 is a cross-sectional illustration taken along the lines 4-4 in FIG. 2.

FIG. 5 schematically illustrates a container assembly including at least one packaging insert within a container with a plurality of silicon wafers.

FIG. 6 is a cross-sectional illustration of another packaging insert embodiment.

FIG. 7 is a cross-sectional illustration of another packaging insert embodiment.

FIG. 8 schematically illustrates a feature of another packaging insert embodiment.

### DETAILED DESCRIPTION

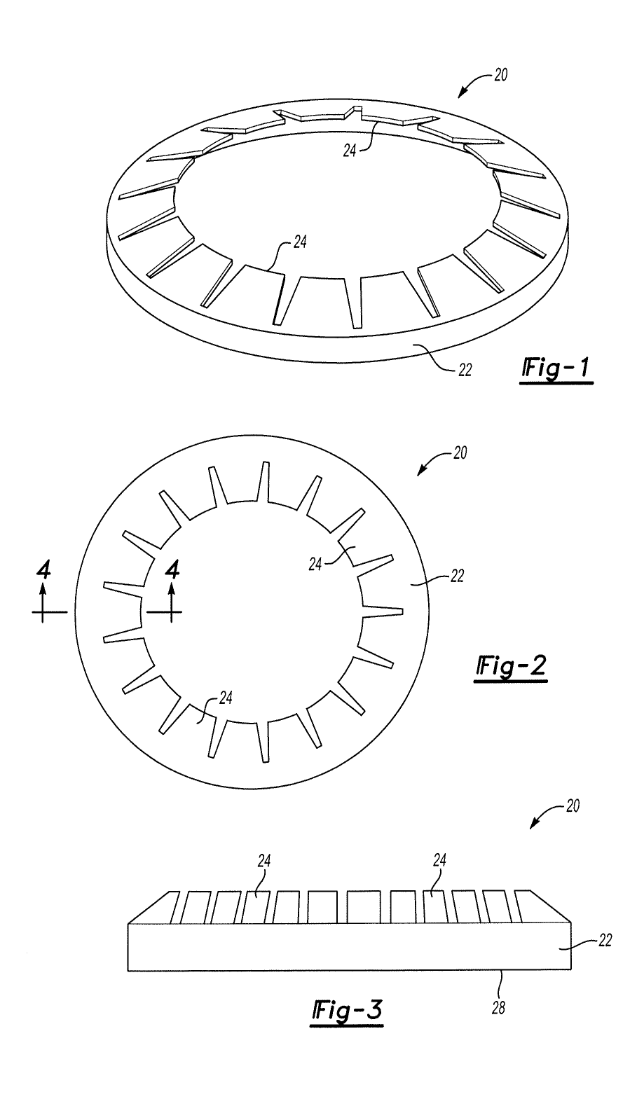

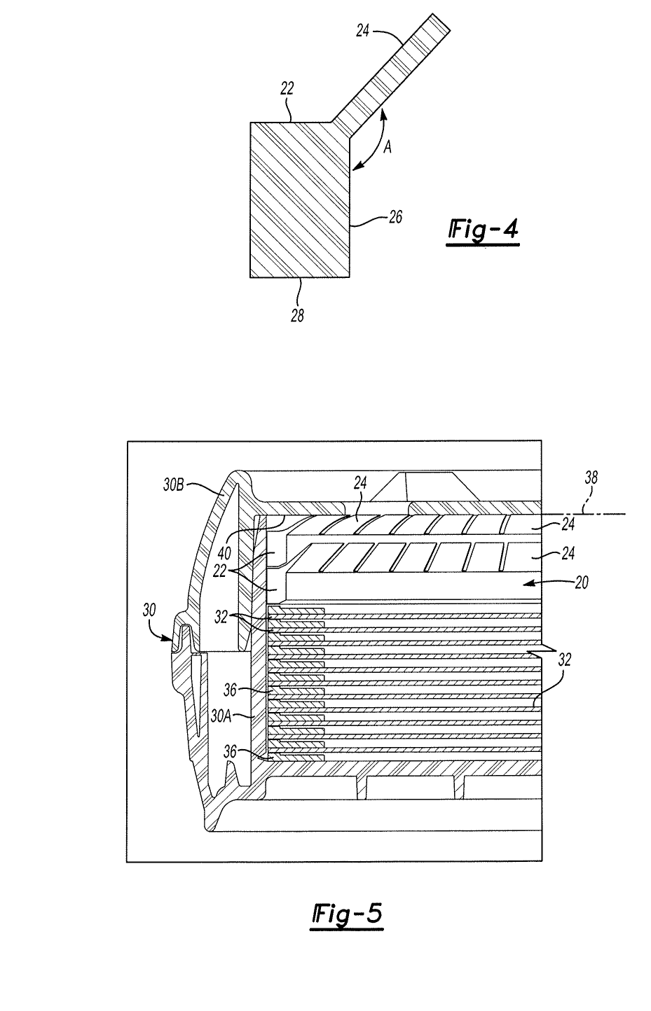

An example embodiment of a packaging insert 20 as shown in FIGS. 1-3 includes a frame portion 22. In this example the frame portion 22 extends around an outer periphery of the insert 20. In this example, the outer periphery is generally circular and the frame portion 22 comprises a ring having a generally rectangular cross-section as can be appreciated from FIG. 4. In this example, the frame portion 22 is generally solid and resistant to compression when exposed to forces typically encountered in a container within which the insert would be placed. In other words, the frame portion 22 has a generally unchanging thickness or height that corresponds to a generally unchanging occupied space within a container when the packaging insert 20 is placed into a container.

The insert 20 includes a plurality of spring members 24 that project from the frame portion 22. In this example, the spring members 24 project generally inward toward a center of the insert 20. The spring members 24 in this example are generally planar in an as-molded or rest position. The spring members 24 thinner in cross-section compared to the frame portion 22. The relatively thinner spring members 24 are more resilient or flexible than the frame portion 22 in a direction along an axis through a center of the frame portion 22.

The spring members 24 project from the frame portion 22 at an oblique angle A as best seen in FIG. 4. The angle A in this example is taken with respect to an inside surface 26 on the frame portion 22. In this example, the inside surface 26 is generally perpendicular to a bottom surface 28 on the frame portion 22. The bottom surface 28 will be oriented generally parallel to a surface of silicon wafers when the insert 20 is received within a container including silicon wafers.

The spring members 24 are at least partially flexible or resilient so that they may flex or move relative to the frame portion 22 responsive to a force imposed on the spring members 24. In some examples, the material used to form the insert 20, the thickness of the spring members 24, or both provide the flexibility that allows the spring members 24 to flex or move as desired. The example insert 20 is molded of a plastic material.

The spring members 24 may flex about a pivot axis established by a living hinge, for example, along the length of the spring members 24 or at an interface between the spring members 24 and the frame portion 22. Alternatively, the spring members 24 may flex or bow at any of a variety of locations along the spring member, depending upon the angle at which the force is applied and the portion of the spring member that is contacted during such force application.

The spring members 24 in this example all have the same length in a direction toward the center of the insert 20. The ends of the spring members 24 that are distal from the frame portion 22 are aligned in a circular pattern. The spring members 24 are equally circumferentially spaced apart and distributed around the frame portion 22.

In some example embodiments the spring members 24 are not all the same. For example, some of the spring members 24 may be longer or thicker than others. Having different spring member configurations allows for having different amounts of spring force or action depending on which of the spring members flex or move. Having differently configured spring members allows for different stages of spring involvement, such as a relatively soft spring effect initially as longer or more flexible spring members 24 flex and a relatively firmer spring effect as shorter or stiffer spring members 24 flex.

FIG. 5 shows a container 30 including a base or container bottom 30A and a lid or container top 30B. A plurality of silicon wafers 32 are situated within the container 30. A plurality of wafer separator rings 36 are situated between the wafers 32 and one separator ring 36 is situated between the lowest wafer (according to the drawing) and a base surface of the container bottom 30A.

When the wafers 32 and separator rings 36 are situated within the container bottom 30A, there is additional axial space (e.g., top-to-bottom according to the drawing) that is not occupied by the wafer stack. If that space is left unoccupied, the wafers may move axially relative to each other within the container (i.e., at least some of the wafers in the stack of wafers may move in an up-and-down direction according to the drawing) during shipping or handling of the container 30.

In this example, a plurality of packaging inserts 20 are placed within the container 30 for occupying the axial space not otherwise occupied by the wafers 32 and wafer separator rings 36. With the inserts 20 within the container 30, there is effectively no unoccupied axial space and the stack of wafers 32 is maintained securely within the container 30 when the top 30B and the bottom 30A are secured together. The frame portions 22 of the inserts 20 have an outer periphery configuration that corresponds to the outer periphery configuration of the separator rings 36. In this example, the outer diameter of the frame portions 22 is approximately equal to an outer diameter of the separator rings 36.

The selected number of the inserts 20 appropriately occupies the space within the container 30 that is not otherwise occupied by the stack of wafers 32 (and in this example, the wafer separator rings 36). In the illustration, the packaging insert 20 that is furthest from the stack of wafers 32 or closest to the open end of the container bottom 30A is situated so that the frame portion 22 is within the boundary of the container bottom 30A as shown schematically at 38. At least some of the length of the spring members 24 extends beyond the interior of the container bottom 30A, which can be appreciated in FIG. 5 by considering that when the container 30 is open, a portion of the spring members 24 will extend beyond the boundary schematically represented at 38. The portion of the spring members 24 extending beyond the boundary 38 (when the container 30 is open) will come into contact with an interior surface 40 on the container top 30B as the container top 30B and container bottom 30A are secured together. When the container 30 is fully closed, the interior surface is aligned with the boundary 38.

The forces associated with closing the container cause the spring members 24 to bend or flex toward the interior of the container 30 (e.g., downward according to the drawing). The resilience or flexibility of the spring members 24 provides a bias on all of the frame portions 22, the wafer separator rings 36 and the wafers 32 within the container 30 so that the wafer stack 32 is maintained securely within the container.

In the example of FIG. 5, the spring members 24 of the more interiorly situated inserts 20 (e.g., the inserts 20 other than the highest one according to the drawing) do not bend or flex because they do not contact a surface that would impose a force on them to cause them to bend or flex. Only the spring members 24 of the upper packaging insert 20 are bowed in FIG. 5. The frame portions 22 of any inserts 20 whose spring members do not interact with the interior surface 40 on the container lid 30B may be considered spacers that occupy space within the container 30 without having any spring-like or compression effect on the contents within the container 30.

Prior to closing the container 30 all of the inserts have a first overall thickness in a direction of the wafer stack (e.g., in a vertical direction in the drawing) established by the frame portions 22 and the spring members 24. When the container bottom 30A and the container top 30B are secured together as shown in FIG. 5, the top insert 20 has a second, smaller overall thickness than the other insert 20 because the spring members 24 of the top insert flex in response to contact with the interior surface 40 on the container top 30B as the container 30 is closed. Each of the inserts 20 has a first overall thickness or height in an as-molded or rest condition and a second, smaller overall thickness or height when its spring members 24 flex or move relative to the frame portion 22.

The frame portions 22 occupy a set amount of axial space within the container 30. The spring members 24 provide an adjustment feature that allows for adjusting the total space occupied by the packaging inserts 20 within the container 30. Including a generally non-compressible frame portion 22 allows for predictably occupying a desired amount of space within a container without introducing an undesired or uncontrolled amount of resiliency or flexibility along an entire distance of a container interior that is not occupied by a wafer stack. The combined solid or generally non-compressible frame portion 22 and the flexible or resilient spring members 24 provides a more secure containment of silicon wafers or other components within a container because the spring members 24 ensure that a bias exists within the container for urging the contents into a desired position within the container. When only one set of spring members is required to bend or flex to achieve such a bias, the forces associated with that bias are known and controlled, which enhances the security of the components, such as silicon wafers, within a container.

FIG. 6 shows another configuration of a packaging insert 20 designed according to an embodiment of this invention. In this example, the frame portion 22 has a rounded cross-sectional profile compared to the generally rectangular shape in the example of FIG. 4. The rounded profile allows the frame portion 22 to rotate or shift within a container, such as the container 30, in response to a force on the spring members 24 that would cause them to move or flex (e.g., a force directed downward in FIG. 6). Even with such rotation of the frame portion 22, the amount of space occupied by the frame portion 22 does not change in this example.

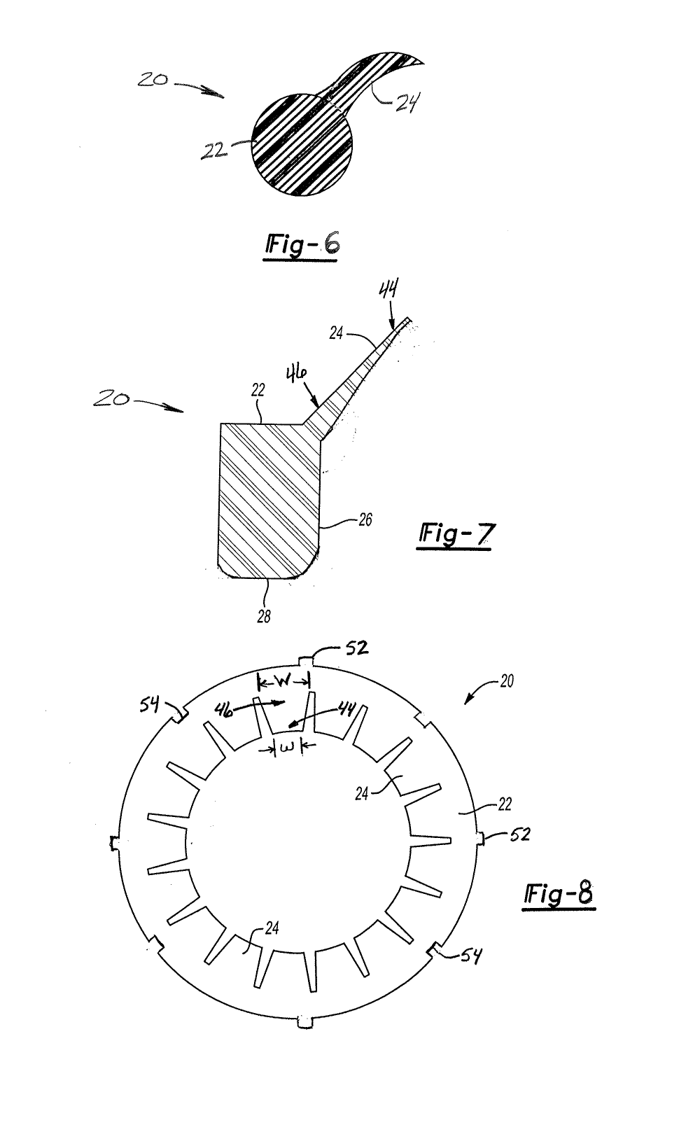

FIG. 7 shows another frame portion configuration. In this example, the frame portion 22 has a generally rectangular cross-sectional profile with at least one rounded area 50 along at least one edge. The rounded area 50 facilitates some rotational movement of the frame portion 22 as a container, such as the container 30, is closed while still having a generally rectangular profile for much of the frame portion 22. A rectangular profile, such as that in the examples of FIGS. 4 and 7, respectively, facilitates a stacking of a plurality of the inserts 20 within a container.

Another feature of the embodiment of FIG. 7 is that a thickness of the spring members 24 is greater closer to the frame portion 22. The portion 44 of the illustrated spring member 24 that is distal from the frame portion 22 is thinner than a more proximal portion 46. The thinner portion 44 will more easily bend or flex in response to a force associated with closing a container in which the insert 20 has been placed compared to the relatively thicker portion 46. This varying thickness allows for a varying amount of compression force on the stack of wafers within the container depending on how much space in the container is unoccupied by the wafer stack as that will affect how much the spring members 24 flex as the container is closed.

FIG. 8 shows another configuration of the spring members 24. In this example, the size of the spring members also changes but in a different dimension or direction compared to the embodiment of FIG. 7. In the example of FIG. 8, the more distal portion 44 of the spring members has a width w that is smaller or thinner compared to the width W of the more proximal portion 46. This example also provides a varying spring effect or a varying amount of compression force depending on how much flex or movement is imposed on the spring members 24.

FIG. 8 illustrates additional features that may be included in some embodiments. In this example, the outer periphery of the frame portion 22 includes a plurality of tabs 52 and a plurality of notches 54. Some embodiments may include only tabs 52 or only notches 54. The tabs 52 or notches 54 are situated and configured to cooperate with a correspondingly configured feature on the inside of a container to establish or maintain an alignment of the insert 20 within the container. For example, a container may have a feature, such as a rib or protrusion, along an interior surface that fits within a notch 54 on the packaging insert 20. The interaction or cooperation between the container feature and the notch 54 limits or prevents rotational movement of the insert 20 within the container.

Various features of several embodiments have been described above and shown in the drawings. Those features are not necessarily limited to the particular embodiment with which they have been shown. It is possible, for example, to incorporate one or more features from one of the embodiments into another one of the embodiments. It is also possible to replace a feature of one embodiment with a feature of another embodiment or to include only selected features of any of the example embodiments in a packaging insert designed according to this invention.

The preceding description is illustrative rather than limiting in nature. Variations and modifications to the disclosed arrangement of features may become apparent to those skilled in the art who have the benefit of this description and such modifications or variations do not necessarily depart from the essence of this invention. The scope of protection given to this invention can only be determined by studying the following claims.

We claim:

1. A packaging insert comprising:
a frame portion that establishes an outer periphery of the insert; and
a plurality of spring members projecting from the frame portion at an oblique angle relative to a surface on the frame portion.

2. The packaging insert of claim 1, wherein the frame portion has an unchanging thickness.

3. The packaging insert of claim 1, wherein the spring members are at least partially resilient and at least partially moveable relative to the frame portion or at least partially flexible.

4. The packaging insert of claim 3, wherein the spring members establish a first overall thickness of the insert in a first position and a second, smaller overall thickness of the insert in a second position corresponding to the spring members being flexed or moved relative to the frame portion.

5. The packaging insert of claim 1, wherein
the frame portion comprises a ring; and
the spring members project inward toward a center of the ring.

6. The packaging insert of claim 5, wherein the frame portion has an at least partially rectangular cross-section.

7. The packaging insert of claim 1, wherein
the spring members have a first portion distal from the frame portion;
the spring members have a second portion proximal to the frame portion;
the first portion has a first dimension; and
the second portion has a second, larger dimension.

8. An assembly, comprising:
a container including a base and a lid, the container having a storage area between the base and lid;
a stack of wafers situated in the storage area, the stack of wafers occupying less than an available space within the storage area; and
at least one packaging insert within the storage area, the at least one packaging insert having a frame portion and a plurality of spring members projecting from the frame portion at an oblique angle relative to a surface on the frame portion.

9. The assembly of claim 8, wherein
the at least one packaging insert is situated between the stack of wafers and an interior surface on at least one of the lid or the base;
the interior surface contacts the spring members of the at least one packaging insert in a manner that causes the spring members to flex or move relative to the frame portion such that the spring members bias the packaging insert toward the stack of wafers.

10. The assembly of claim 9, wherein
the at least one packaging insert comprises a plurality of packaging inserts; and
the spring members of only one of the packaging inserts flex or move responsive to contact with the interior surface.

11. The assembly of claim 10, wherein the frame portion of at least one of the packaging inserts whose spring members do not flex or move serves as a spacer within the container.

12. The assembly of claim 8, wherein
the frame portion and the spring members have a first overall thickness when the container is open and a second, smaller thickness when the container is closed with the lid is secured to the base.

13. The assembly of claim 8, wherein the spring members are situated relative to the frame portion differently when the container is closed with the lid secured to the base compared to when the container is open.

14. The assembly of claim 8, wherein the frame portion has an unchanging thickness.

15. The assembly of claim 8, wherein the spring members are at least partially resilient and at least partially moveable relative to the frame portion or at least partially flexible.

16. The assembly of claim 15, wherein the spring members establish a first overall thickness of the packaging insert in a first position and a second, smaller overall thickness of the packaging insert in a second position corresponding to the spring members being flexed or moved relative to the frame portion.

17. The assembly of claim 8, wherein
the frame portion comprises a ring; and
the spring members project inward toward a center of the ring.

18. The assembly of claim 8, wherein the frame portion has an at least partially rectangular cross-section.

19. The assembly of claim 18, wherein the cross-section is at least partially rounded.

20. The assembly of claim 8, wherein
the spring members have a first portion distal from the frame portion;
the spring members have a second portion proximal to the frame portion;
the first portion has a first dimension; and
the second portion has a second, larger dimension.
